(19) United States
(12) Patent Application Publication
(10) Pub. No.: US 2003/0179607 A1
(43) Pub. Date: Sep. 25, 2003

(54) Writing method in memory and writing method for memory for a card reader

(75) Inventor: Tsutomu Orii, Nagano (JP)

Correspondence Address: HOGAN & HARTSON L.L.P., 500 S. GRAND AVENUE, SUITE 1900, LOS ANGELES, CA, 90071-2611, US

(73) Assignee: SANKYO SEIKI MFG. CO., LTD.

(21) Appl. No.: 10/390,575

(22) Filed: Mar. 17, 2003

(30) Foreign Application Priority Data
Mar. 18, 2002 (JP) 2002-073775

(51) Int. Cl. G11C 7/00

(52) U.S. Cl. 365/189.07

(57) ABSTRACT

A writing method includes writing data required to be updated respectively and sequentially in a first, a second and a third memory when a writing operation is performed and comparing data in the first, second and third memories with each other when a power source is supplied. A last writing operation is determined to be successful when the three data are the same and determined to be unsuccessful when any of the three data does not match.

### BACKGROUND OF THE INVENTION

1. Field of the Invention

The present invention relates to a writing method for the content in a memory which is preferably used to store the number of times a card reader handles cards.

1. Description of Related Art

Card readers which perform reading and/or writing of data on an information recording medium, for example, a card, generally have a memory which stores the number of times the card reader has either read data from or written data to a card. The content of the memory is used for a standard number of times for the service life of a magnetic head or Integrated Circuit (IC) contactors in a card reader.

For example, when recording and reading of magnetic data are repeatedly performed for a magnetic card, a magnetic head in the card reader gradually deteriorates and is unable to precisely perform the recording/reading of magnetic data due to, for example, contamination due to the adherence of dust or the like and wear by contacting with magnetic cards. The magnetic head needs to be replaced because of its limited service life.

In order to indicate the appropriate replacement time of a magnetic head, a method is known in which the number of times the card reader has handled cards is counted and a magnetic head or the like is replaced when the prescribed card handling number of times is exceeded. The counter can be realized, for example, by writing a counter value in one counter region of a flash memory. When a power source for the card reader is disconnected and then re-supplied, the succeeding procedures are executed on the basis of the counter written in the flash memory.

However, in the above-mentioned writing method in a memory, when an interruption in power occurs while a writing operation is performed in the counter region of the memory, the writing process is interrupted, which may result in an incorrect counter value. When an incorrect counter value occurs, the succeeding procedures are executed on the basis of the incorrect counter value because the card reader is unable to determine whether the counter value is correct or not when the power source has been subsequently connected.

In order to prevent this problem, a writing method in a memory may be conceivable in which a check data is added to determine whether the counter value is correct or not. However, this method cannot restore the counter to the correct value even though an incorrect counter value can be detected.

### SUMMARY OF THE INVENTION

In view of the problems described above, it is an advantage of the present invention to provide a writing method for content in a memory capable of restoring a correct value even when an interruption of power occurs during a writing operation, which causes an incorrect recording, and to provide a writing method for content in a memory of a card reader.

In order to achieve the above advantage, according to the present invention, there is provided a writing method in a memory for writing data that is required to be updated into data stored in a storage section. The storage section is provided with at least a first, a second and a third memory which respectively and successively store the data that is required to be updated. When a writing operation is performed the data is sequentially written in the first, the second and the third memory in order. In addition, when power is supplied, the data of the first, second, and third memories are compared with each other, and the last writing operation is determined to be successful in the case that all of the three data are the same, but when any of the three data does not coincide with one another, the last writing operation is determined to be unsuccessful.

Also, according to the present invention, there is provided a writing method in a memory for a card reader including a sensor which detects a card traveling through a card transportation passage and a storage section which stores a count value of the number of times cards travel through the card passage from an output of the sensor. The storage section is provided with at least a first, a second and a third memories which respectively and successively store the count value. When a writing operation is performed in a memory, the same count value is sequentially written in the first, the second and the third memory in order. In addition, when a power source is supplied, the data of the first, second, and third memories are compared with each other, and the last writing operation is determined to be successful in the case that all of the three data are the same, but when any of the three data does not coincide with each other, the last writing operation is determined to be unsuccessful.

In accordance with an embodiment of the present invention, the same data content is written in at least three places and they are compared with each other. Therefore, the last writing operation can be readily determined whether it is successful or unsuccessful, and thus a countermeasure can be readily taken on the basis of the result.

In accordance with an embodiment of the present invention, when it is determined to be unsuccessful, the correct value is judged, for example, by a majority decision of three data. Therefore, the correct value (count value) of the memories can be obtained even when one of the data is not correct.

When it is determined to be unsuccessful, the memory of the unsuccessful result can be specified on the basis of the writing-in order of the three data. In the case that the value of the memory written before the writing in the unsuccessful memory is determined to be correct, the value of the memory is already updated and thus another memory is written to the updated correct value. On the other hand, when the value of the memory written after the writing in the unsuccessful memory is determined to be correct, all the memories are incremented by one.

The present invention can be applied to a card reader which is provided with a magnetic head for recording or reading magnetic data from a card or contactors for IC card for being brought into contact with contact terminal patterns of an IC card in order that the service life of the magnetic head and the contactors for IC card can be estimated.

### BRIEF DESCRIPTION OF DRAWINGS

FIG. 1 is a flow chart showing an example of process in a writing method of content in a memory according to the present invention, wherein FIG. 1 (A) shows a writing process and FIG. 1 (B) shows a reading process.

FIG. 2 is a block diagram showing a control circuit of a card reader.

FIG. 3 is a schematic side view showing the card reader.

FIG. 4 is a schematic plan view showing the card reader.

FIG. 5 is a schematic side view showing a front side detection sensor.

### DETAILED DESCRIPTION OF THE PREFERRED EMBODIMENTS

Preferred embodiments of the present invention will be described in detail below with reference to the accompanying drawings.

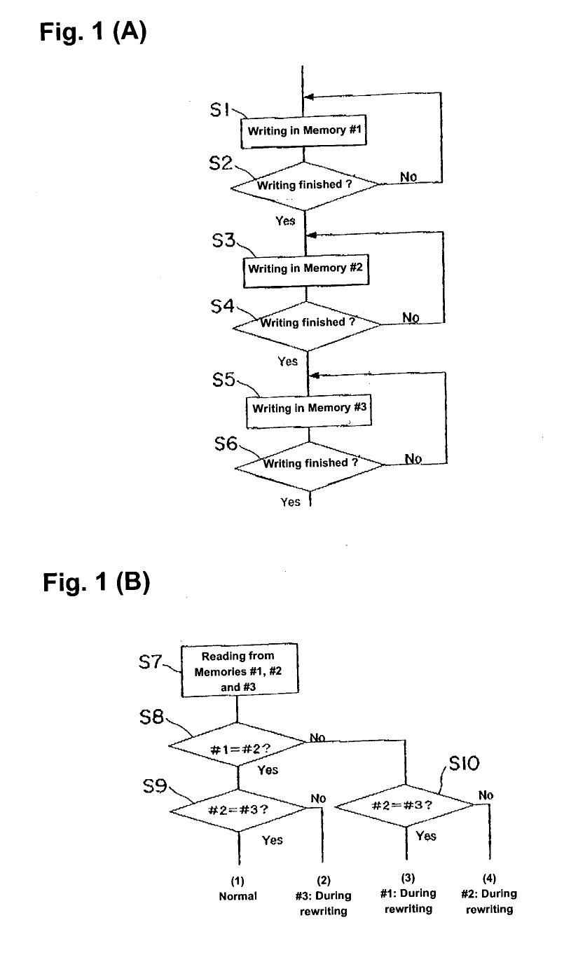

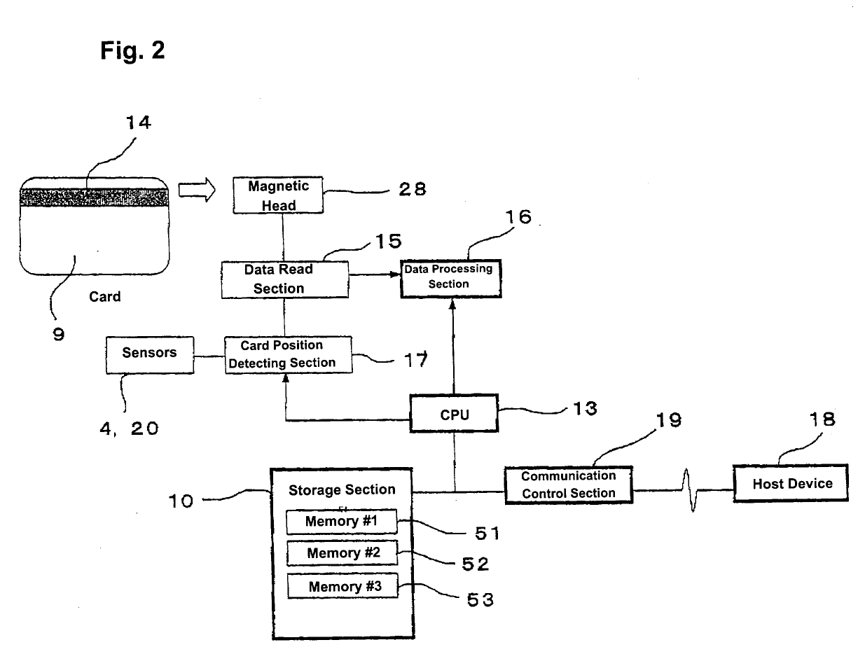

An example of executing a writing method for content in a memory according to the present invention is shown in FIGS. 1 and 2. In this writing method for content in a memory, the data, for example, a count value, stored in a storage section 10 is incremented by one. The storage section 10 is provided with a first memory 51, a second memory 52 and a third memory 53 for successively storing the same data required to be updated. When written in the memories, the content is written in order in the first memory 51, the second memory 52, and then the third memory 53 sequentially. In addition, when a power source is turned on, the data in the first memory 51, the second memory 52 and the third memory 53 are respectively compared with each other. When all of the three data are the same as each other, the last write-in operation is determined to be a successful, but when the three data do not coincide with each other, the last write-in operation is determined to be unsuccessful when an error is generated during the writing operation. In this way, the same data content is written in at least three places and the written data contents are compared with each other. Therefore, whether the last writing operation is successful or unsuccessful can be easily judged.

When the last writing operation is determined to be unsuccessful, a correct value can be determined based on the majority of the three data. Since the correct value is judged by the decision of the majority, the correct value of the memories can be obtained even though one of the data in one of the three memories is not correct.

All the memories 51, 52 and 53 respectively and successively storing the same content are provided in one storage element.

An example of the above-mentioned writing method of content in a memory is, for example, applied to the number of times a card reader 1 handles cards. The card reader 1 is equipped with sensors (referred to as card travel detection sensor) 4 and 20 for detecting a card 9 traveling in a card transportation passage 8, a storage section 10 for storing a count value of the number of times the cards travel in the transportation passage 8 using the outputs from the card travel detection sensors 4 and 20, and a CPU 13 for controlling reading and writing operation of the count data in the storage section 10. The storage section 10 is provided with at least three memories 51, 52 and 53 for storing the same count value successively. When power is supplied, the data of the first memory 51, the second memory 52, and the third memory 53 are respectively compared with each other. In the case all of the three data are the same, the writing of the count data is judged to be successful when an interruption of power occurs and when the three data do not coincide with each other, the writing is judged to be unsuccessful when an interruption of power occurs. In addition, the correct value is determined by majority decision making of the three data. As described above, the same data is written in at least three places and the written data are compared with each other to determine the correct value by the majority decision. As a result, even when one of the data is not correct, the correct counter value can be obtained.

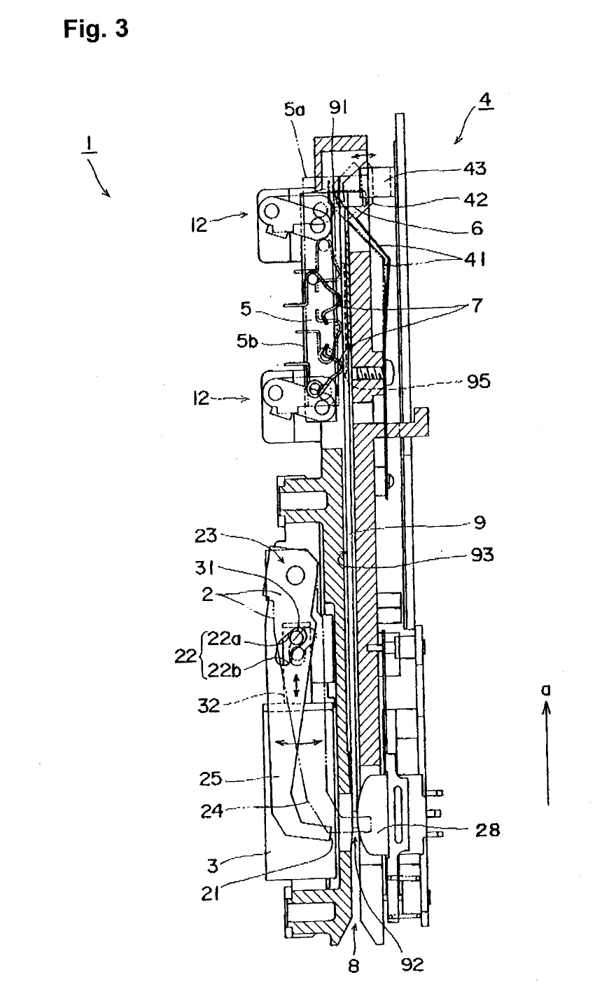

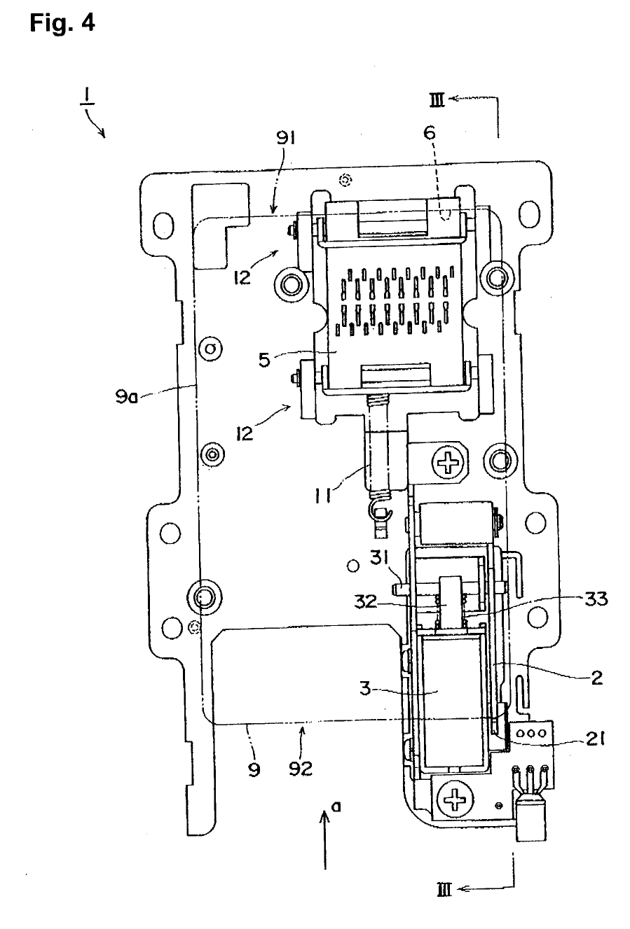

As shown in FIG. 3 to FIG. 5, the card reader 1 according to the present embodiment is provided with a card lock member 2 moved by a solenoid 3. The inserted card 9 is locked by a lock part 21 of the card lock member 2 at a card insertion completed position 9a (two-dot chain line shown in FIG. 4). In addition, the card reader 1 is provided with detection sensors 4 and 20 for detecting the insertion of the card 9.

The card lock member 2 is mounted on a frame of the card reader 1 so as to be capable of moving between a card lock position 24 and a card unlock position 25 around a support shaft 23. The card lock member 2 includes the lock part 21, which abuts with the rear end part 92 of the card 9 for locking and preventing the card 9 from pulling out from the card reader 1. This lock part 21 is constituted so that its abutting portion with the rear end part 92 of the card 9 is formed, for example, in a hooked shape so as to catch the rear end 92 of the card 9. In the card lock position 24, the lock part 21 prevents the card 9 from moving on the rear end part 92 side by positioning across the card transportation passage 8.

An engagement hole 22 is provided between the support shaft 23 that is a rocking center in the card lock member 2 and the lock part 21. An engaging pin 31 provided at a tip end of a plunger 32 of a solenoid 3 is fitted to the engagement hole 22 and thus the card lock member 2 is interlocked with movement of the solenoid 3. The engagement hole 22 is comprised of a shifting aperture part 22a that is formed slanted with respect to the axis of the plunger 32 and a holding aperture part 22b approximately parallel to the axis and formed so as to communicate with the shifting aperture part 22a smoothly. The shape of the engagement hole 22 is formed as the shape being bent in the middle as shown in FIG. 3. Therefore, when the plunger 32 protrudes from the main body of the solenoid 3, the engaging pin 31 is located at the end part side of the shifting aperture part 22a and the card lock member 2 is located at the card unlock position 25 where its lock part 21 is retreated from the card transportation passage 8. In this state, when the plunger 32 is pulled to the main body side of the solenoid 3, the engaging pin 31 is moved and slid on the edge of the shifting aperture part 22a and thus the card lock member 2 begins to swing on the card lock position 24 side. And, when the engaging pin 31 is located at the holding aperture part 22b, the card lock member 2 is held to be unable to swing while the card lock member 2 is located at the card lock position 24. On the other hand, when the plunger 32 is moved in the opposite direction for protruding from the main body of the solenoid 3, the card lock member 2 is released from the locking state to swing to the card unlock position 25.

The solenoid 3, which makes the card lock member 2 swing between the card lock position 24 and the card unlock position 25 by moving the plunger 32 back and forth, is mounted on a frame with its main body fixed thereon. The engaging pin 31 is fitted at the tip part of the plunger 32, which gives a reciprocal linear-motion, so as to be arranged to be approximately perpendicular to the axial direction of the plunger 32 as shown in FIG. 4. A coil spring 33 for returning is provided around the plunger 32 to urge the plunger 32 in the protruding direction. Therefore, the plunger 32 is protruded by the urging force of the coil spring 33 for returning at the time of an “OFF” state when the coil of the solenoid 3 is not energized. On the other hand, when the solenoid 3 is activated to be at an “ON” state by energizing the coil, the plunger 32 is retreated to the main body side of the solenoid 3 by an electromagnetic force. In other words, according to the present embodiment, when the solenoid 3 is activated to be at an “ON” state, the card lock member 2 is swung to the card lock position 24 and held at the lock state, and further, when the operation of the solenoid 3 is released and become to be at an “OFF” state, the card lock member 2 can return to the card unlock position 25.

The back side detection sensor 4 is mounted as a means for detecting the card 9 inserted into the card reader 1 and for activating the solenoid 3. The back side detection sensor 4 is arranged to detect the card 9 having reached the card insertion finish position 9a, which is the farthest traveling position of the card. The back side detection sensor 4 may be mounted so as to detect the card 9 at least before the card reaches the card insertion finish position 9a. In this case, the card lock member 2 is allowed to be moved when the card 9 has not been completely inserted in the card insertion finish position 9a yet. In this example, when the insertion of the card 9 is detected, the card lock member 2 is moved by the operation of the solenoid 3 so that the tip face of the lock part 21 contacts with the upper face 93 of the card. As the card 9 is inserted further, the tip face of the card lock member 2 relatively slides on the upper face of the card 9, and at the position where the card 9 approximately reaches the card insertion finish position 9a, the card lock member 2 is disengaged from the card rear end 92 and moves to the card lock position 24.

In the present embodiment, a combination of a sensor spring 41 and a photo interrupter 43 is used as the back side detection sensor 4 as shown in FIG. 3. The sensor spring 41 is arranged in such a manner that a part of the sensor spring 41 is located in the card transportation passage 8 to be bent by abutting with the front end part 91 of card 9. A screening plate part 42 is provided at the tip end of the sensor spring 41 and interrupts the light by traversing the photo interrupter 43 due to the card pressing the sensor spring 41. Therefore, the insertion of the card 9 is detected by interrupting the light in the detection sensor 4. The detection sensor 4 is not limited to such an optical detection type sensor but other types of sensors such as a micro switch may be utilized. Also, as for the timing for detecting the card insertion, any timing can be used for detecting the card insertion if the card is detected after the card front end part 91 has passed through the lock part 21 as described above. As long as located within this region, the detection sensor 4 may be positioned in any place. The detection sensor 4 according to the present embodiment is provided so as to detect the card 9 before or at the moment it reaches the card insertion finish position 9a as described above. The detection sensor 4 is constituted to have an additional coverage so as not to come out from the detection region even when the card 9 is forcibly moved back and forth a little under the condition that the card is locked at the card insertion finish position 9a.

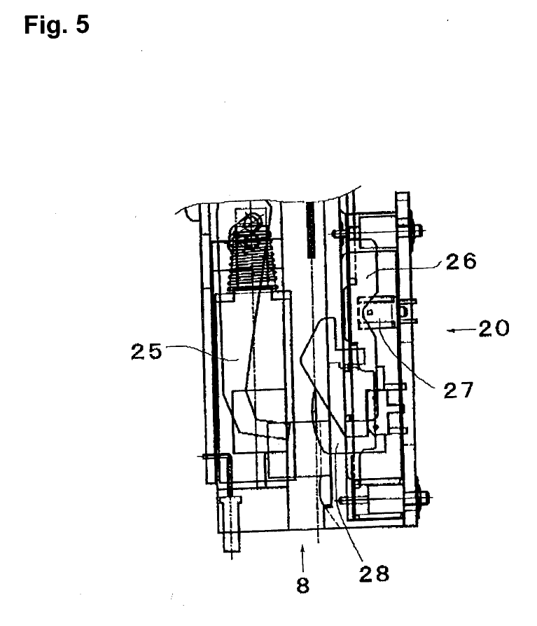

A combination of a sensor spring 26 and a photo interrupter 27 is used as a front side detection sensor 20 as shown in FIG. 5. A part of the sensor spring 26 is located in the card travel passage 8 and pressed by the front end part 91 of the card 9 to be retreated from the card transportation passage 8 and a photo interrupter 27 shaded the light. Therefore, the insertion of the card 9 is detected by shading the light in the front side detection sensor 20. The front side detection sensor 20 is not limited to such an optical detection type sensor but other types of sensors such as a micro switch may be utilized.

In the present embodiment, the card 9 is inserted and the front side detection sensor 20 is turned on, and then the card 9 travels further and the back side detection sensor 4 is turned on. After a predetermined processing for the card has been completed the card 9 is pulled out, and when both the back side detection sensor 4 and the front side detection sensor 20 are turned off, a counting operation is performed by a counter.

The card reader 1 is provided with a contactor carriage 5 for an IC card, which comprises a card abutting part 6 for abutting with the front end part 91 of the card 9 and elastic contactors 7 for contacting with IC contact terminal patterns 95 of the card 9 when the card 9 is an IC card. The contactor carriage 5 moves obliquely with the insertion of the card 9 and reaches a contact location 5a in the card insertion finish state. The contactor carriage 5 is mounted on a frame constituting the card reader 1 so as to move obliquely while the contactor carriage 5 and maintained in parallel to the card transportation passage 8 by a parallel link mechanism 12 as shown in FIG. 3. The parallel link mechanism 12 is constituted of two pair links of the same shape as shown in FIG. 3 to swing the contactor carriage 5 in parallel to the card transportation passage 8. The contactor carriage 5 is energized by a biasing means 11 in the opposite direction to the “a” direction in FIG. 3, that is, on the card rear end 92 side. Therefore, when the card 9 is not inserted, the contactor carriage 5 is positioned at a non-contact location 5b as shown in a solid line in FIG. 3.

In the direction “a” of the contactor carriage 5, the card abutting part 6 is integrally formed in the contactor carriage 5 so as to protrude across the card transportation passage 8. Therefore, when the front end part 91 of the card 9 which travels along the card transportation passage 8 abuts against the card abutting part 6, the contactor carriage 5 is pressed by the card 9 in the direction of “a” and swung in parallel with respect to the passage 8.

Contactors 7 for an IC card are provided in the contactor carriage 5 so as to protrude from a side surface of the contactor carriage 5 on the card passage side for contacting the card 9 and performing data communication. Elasticity of a copper wire which forms the respective contactors 7 is utilized as a pressing force against the card 9. The contactors 7 are arranged in such a manner that the contactors 7 are located at a prescribed position with respect to contact terminal patterns 95 of the card 9 when the front end part 91 of the card 9 abuts with the card abutting part 6 of the contactor carriage 5. As the card 9 is inserted further, the contactor carriage 5 is moved in the “a” direction the same amount as the card 9. Therefore, the contactors 7 come close while maintained to face to the card, and then the contactors 7 come into contact with the contact terminal patterns 95. The contactors 7 are arranged so as to contact with the terminal patterns 95 before the card 9 reaches the card insertion finish position 9a.

The card reader 1 according to the present embodiment is provided with a magnetic head 28 and is a card reader capable of using, for example, a magnetic and IC card.

A control circuit for controlling the card reader 1, as shown in FIG. 2, comprises a CPU 13 including a comparing section for comparing the above-mentioned count values and for controlling the entire circuit operation, a storage section 10, a data read section 15 which is connected to the magnetic head 28, a data-processing section 16 for processing data from the data read section 15, a card position detecting section 17 which is connected to the sensors 4 and 20, and a communication control section 19 for connecting the control circuit with a host device 18 with respect to the card reader 1.

The storage section 10 is constituted of a rewritable nonvolatile memory such as a flash memory, an EEPROM (Electrically Erasable Programmable ROM), an FRAM (Ferroelectric RAM), or the like. The memories 51, 52 and 53 for successively storing the value of a counter are formed on one storage element.

The counter counts the number of times of cards handled by the card reader. For example, when a card is used in the card reader, the value of the counter is increased by one. The value of the counter, the accumulated number of times, is written to the storage section 10. The value is increased by one whenever a card is used in the card reader. Specifically, the number of times is increased when data processing for the card is finished and sensors are turned off.

At first, the number of times is set to be “0”, when an object (a component) whose service life is to be detected is new. The number is increased whenever a card is used. The required number of times is determined according to the object, for example, a magnetic head, IC contactors or other components.

The number of times is initialized, that is, set to be “0” again when the object is replaced at the time when the object is judged to have reached the end of its service life.

The counter is not limited to a processing by the CPU 13 but may be composed of a dedicated circuit in which the accumulated traveling number of times is counted up and the new accumulated traveling number of times is stored in the storage section 10 by detecting that, for example, data read processing from the card 9 is finished and respective sensors 4, 20 are turned off.

An embodiment of an operation of the card reader 1 in which the above-mentioned recording method is applied is described below. When a card 9 is inserted into a card transportation passage 8, a front side detection sensor 20 is turned on. Then the card 9 is further traveled and a back side detection sensor 4 is turned on. At this moment, a card lock member 2 closes a card transportation passage and the position of the card 9 is locked. Simultaneously, a contactor carriage 5 is moved to the card and the processing of the data with the card 9 is executed. After the predetermined processing is finished, the card lock member 2 is opened and the card 9 is pulled out from the card reader 1, and then the back side detection sensor 4 and the front side detection sensor 20 are turned off in succession, and a counter counts up.

Accordingly, the counter can count the number of times that a card 9 passes through a magnetic head 28 and the number of times that a contactor carriage 5 is moved to tightly contact with a card by means of the accumulated traveling number of times of a card 9 in the card transportation passage 8. The accumulated traveling number of times can be considered as a factor that influences directly on the service life of the magnetic head 28 due to wear or the like, and it may be also a factor that affects the service life of other parts of the card reader which are used to transport the card 9.

Therefore, in the card reader 1 constituted as described above, the service life of the object to be detected such as the magnetic head 28, contactors 7 or main body parts of the card reader 1 can be detected as follows.

The CPU 13 confirms the presence/absence of the detection signal from respective detection sensors 4 and 20. Whenever a card 9 passes through the magnetic head 28 and moves the contactor carriage 5 to make the contactors 7 come into contact with the card, the respective detection sensors 4 and 20 detect the insertion or discharge of the card 9 and detection signals are outputted to the CPU 13. When the CPU 13 detects the detection signal, a writing operation is executed, in which the accumulated number of times a card travels through the card passage of the first memory 51 in the storage section 10 is counted up by one (step1/S1). When the writing operation in the first memory 51 is finished (step2/S2; Yes), write-in operation in which the accumulated number of times a card travels through the card passage of the second memory 52 is counted up by one is executed (step 3/S3). When the writing operation in the second memory 52 is finished (step4/S4; Yes), writing operation in which the accumulated number of times a card travels through the card passage of the third memory 53 is counted up by one is executed (step5/S5). When the writing operation in the third memory 53 is finished (step6/S6; Yes), a series of count up processing is completed.

For the case an interruption of power occurs during the writing operation in the storage section 10, the following processes are performed. When power is subsequently re-supplied, reading operations are executed from respective memories 51, 52 and 53 of the storage section 10 (step7/S7). Then, it is determined whether respective count values of the first memory 51 and the second memory 52 are equal or not (step8/S8). When the two values are equal (step8/S8; Yes), it is determined whether respective count values of the second memory 52 and the third memory 53 are equal or not (step9/S9). When the two values are also equal (step9/S9; Yes), all of the counter values are judged to be correct since all values are equal in the three memories 51, 52 and 53.

When the respective count values of the first memory 51 and the second memory 52 are equal (step8/S8; Yes) but the respective count values of the second memory 52 and the third memory 53 are different (step9/S9; No), it is judged that an interruption of power has occurred during the writing operation of the third memory 53. Therefore, the count value of the first memory 51 and the second memory 52 is regarded as the correct count value and thus the value of the third memory 53 is rewritten to the correct count value.

When the respective values of the first memory 51 and the second memory 52 are different (step8/S8; No) but the respective values of the second memory 52 and the third memory 53 are equal (step10/S10; Yes), it is judged that an interruption of power supply has occurred during the writing in the first memory 51. Therefore, the value incremented by one to the value of the second memory 52 and the third memory 53 is regarded as the normal count value and thus the added count value is written in the respective memories 51, 52 and 53.

When the respective values of the first memory 51 and the second memory 52 are different (step8/S8; No) and the respective values of the second memory 52 and the third memory 53 are also different (step10/S10; No), it is judged that an interruption of power supply has occurred during the writing in the second memory 52. Therefore, the value of the first memory 51 is regarded as the correct count value and thus the value of the first memory 51 is written in both the second memory 52 and the third memory 53.

As described above, according to the recording method of the present embodiment, a correct value is determined by a majority decision with the data in the three memories 51, 52 and 53. Accordingly, even when an interruption of power changes any of the data in the memories to an incorrect value, the detection of an error and the correction of the error can be performed by using the data in the other memories. Therefore, since the precision of the accumulated number of times a card travels through the card passage of a card 9 is ensured, the magnetic head and other parts of the card reader 1 can be changed before they expire by means of the host device 18 reading the count value through the communication control section 19.

According to the writing method of the present embodiment, since the writing of a count value is executed in the three memories 51, 52 and 53 in a prescribed order as shown in FIG. 1 (A), a correct count value can be obtained by a decision method as shown in FIG. 1 (B). The count value of the card handling number of times is increased sequentially one by one. Therefore, even when the correct count value has not been written in any of the memories 51, 52 and 53 because of an interruption in power during the writing operation of the first memory 51, the correct count value can be restored from the last correct count value.

Although the present invention has been shown and described with reference to specific preferred embodiments, various changes and modifications will be apparent to those skilled in the art from the teachings herein. For example, in the above-mentioned embodiment, the same count value is stored in each of the three memories 51, 52 and 53, but the count value may be preferably stored in at least three places or more, that is, it may be stored, for example, in four memories, five memories or more.

In addition, all of the above-mentioned memories 51, 52 and 53 are formed on one storage element, but they may be formed of discrete storage elements.

In the above-mentioned embodiment, when the respective data of the memories 51, 52 and 53 do not coincide with each other, the correct value is determined by a majority decision, but a warning alarm may be taken outside at the time of detecting an incorrect writing operation.

In the above-mentioned embodiment, the writing method of content in a memory is applied to a manual card reader 1, but the present writing method may be applied to a card reader in which a card travels by a motor. In addition, the writing method in a memory according to the present invention is applied to an accumulation counter of the number of times a card travels through the card passage in which a count is executed at every time a card processing is completed. However, the accumulation counter may be constituted so as to count every card traveling operation performed during one handling process of a card, for example, the entire card traveling number of times with respect to a magnetic head. Besides, the present writing method in a memory is not limited to a card, but it may be applied to various kinds of counter devices for counting.

As described above, the writing method in a memory or the writing method in a memory for a card reader according to the present embodiment is performed in such a manner that when a power source is supplied, the data of three memories are compared with each other, and the last writing operation is determined to be successful in the case that all of the three data are the same, but when any of the three data does not coincide with another data, the last writing operation is determined to be unsuccessful. Accordingly, even when one of the data of the memories has an incorrect value by the interruption of power, the incorrect value can be detected at the time power is later supplied and thus a countermeasure such as rewriting in the correct value can be carried out.

Also, according to the present embodiment, when power is supplied, the data of three memories are compared with each other, and when any of the three data does not coincide with each other, the correct value can be determined by a majority decision from the three data. Accordingly, even when an interruption of power causes a change in any of the data of the memories to become incorrect, the detecting and correction of an error can be performed by using the other two data. Therefore, since the precision of the accumulated number of times a card travels through the card passage is ensured, a magnetic head and other parts of a card reader can be replaced before they expire.

While the description above refers to the particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A method for writing in a memory comprising:
writing data required to be updated respectively and sequentially in a first, a second and a third memory when a writing operation is performed;
comparing data in the first, second and third memories with each other when a power source is supplied;
determining a last writing operation to be successful when the three data are the same; and
determining the last writing operation to be unsuccessful when any of the three data does not match.

2. The writing method according to claim 1, further comprising:
making a majority decision when the last writing operation is determined to be unsuccessful; and
determining a correct value by the result of the majority decision.

3. The writing method according to claim 2, further comprising:
specifying which of the first, second or third memory had the unsuccessful writing operation on the basis of a writing order;
determining the value in the first, second or third memory written before the unsuccessful writing operation as the correct value; and
writing the correct value in the first, second or third memory in another memory.

4. The writing method according to claim 2, further comprising:
specifying which of the first, second or third memory had the unsuccessful writing operation on the basis of a writing order;
determining the value in the first, second or third memory written after the unsuccessful writing operation as the correct value; and
incrementing each of the memories by one.

5. A writing method in a memory for a card reader comprising:
writing a count value respectively and sequentially in a first, a second and a third memory when a writing operation has been performed;
comparing the count values of the first, second and third memories with each other when a power source is supplied;
determining a last writing operation to be successful when all of the three count values are the same; and
determining the last writing operation to be unsuccessful when the three count values do not coincide with each other.

6. The writing method according to claim 5, further comprising:
making a majority decision when the last writing operation is determined to be unsuccessful; and
determining a correct value by the result of the majority decision.

7. The writing method according to claim 6, further comprising:
specifying which of the first, second or third memory had the unsuccessful writing operation on the basis of a writing order;
determining the count value in the first, second or third memory written before the unsuccessful writing operation as the correct value; and
writing the correct count value of the first, second or third memory in another memory.

8. The writing method according to claim 6, further comprising:
specifying which of the first, second or third memory had the unsuccessful writing operation on the basis of a writing order;
determining the count value in the first, second or third memory written after the unsuccessful writing operation as the correct value; and
incrementing each of the memories by one.

9. The writing method according to claim 5, further comprising:
providing in the card reader with at least one of a magnetic head for recording or reading magnetic data from a card and contactors for an integrated circuit (IC) card for being brought into contact with contact terminal patterns of an IC card.

10. The writing method according to claim 5, further comprising counting the number of times cards travel through a transportation passage of the card reader based on an output from a sensor for detecting a card traveling through the card transportation passage.

11. A memory writing device comprising:
a first, a second and a third memory sequentially receiving data to be updated;
a controller that compares data in the first, second and third memories with each other when a power source is supplied; and
a processor that determines a last writing operation to be successful when the three data are the same and determines the last writing operation to be unsuccessful when any of the three data does not match.

12. The writing device according to claim 11, wherein the processor makes a majority decision when the last writing operation is determined to be unsuccessful and determines a correct value by the result of the majority decision.

13. The writing device according to claim 12, wherein the processor specifies which of the first, second or third memory had the unsuccessful writing operation on the basis of a writing order; determines the value in the first, second or third memory written before the unsuccessful writing operation as the correct value; and writes the correct value in the first, second or third memory in another memory.

14. The writing device according to claim 12, wherein the processor specifies which of the first, second or third memory had the unsuccessful writing operation on the basis of a writing order; determines the value in the first, second or third memory written after the unsuccessful writing operation as the correct value; and incrementing the memories by one.

15. A writing device for a card reader comprising:
a first, a second and a third memory that receives a count value respectively and sequentially;
a controller that compares the count values of the first, second and third memories with each other when a power source is supplied; and
a processor that determines a last writing operation to be successful when all of the three count values are the same and determines the last writing operation to be unsuccessful when the three count values do not coincide with each other.

16. The writing device according to claim 15, wherein the processor makes a majority decision when the last writing operation is determined to be unsuccessful and determines a correct value by the result of the majority decision.

17. The writing device according to claim 16, wherein the processor specifies which of the first, second or third memory had the unsuccessful writing operation on the basis of a writing order; determines the count value in the first, second or third memory written before the unsuccessful writing operation as the correct value; and writes the correct count value of the first, second or third memory in another memory.

18. The writing device according to claim 16, wherein the processor specifies which of the first, second or third memory had the unsuccessful writing operation on the basis of a writing order; determines the count value in the first, second or third memory written after the unsuccessful writing operation as the correct value; and incrementing the memories by one.

19. The writing device according to claim 15, further comprising at least one of a magnetic head for recording or reading magnetic data from a card and contactors for an integrated circuit (IC) card for being brought into contact with contact terminal patterns of an IC card.

20. The writing device according to claim 15, further comprising a counter that counts the number of times cards travel through a transportation passage of the card reader based on an output from a sensor for detecting a card traveling through the card transportation passage.
